(19) United States
(12) Patent Application Publication
(10) Pub. No.: US 2021/0041508 A1
(43) Pub. Date: Feb. 11, 2021

(54) RESOLVER SIGNAL PROCESSING CIRCUIT

(71) Applicant: DENSO CORPORATION, Kariya-city (JP)

(72) Inventors: Hirokazu SADAMATSU, Kariya-city (JP); Shinichiro NAKATA, Kariya-city (JP); Makoto OISHI, Toyota-shi (JP)

(21) Appl. No.: 17/079,653

(22) Filed: Oct. 26, 2020

Related U.S. Application Data
(63) Continuation of application No. PCT/JP2019/015441, filed on Apr. 9, 2019.

(30) Foreign Application Priority Data
Jun. 19, 2018 (JP) 2018-116196

(51) Int. Cl. G01R 31/52; H03F 3/45; H03M 1/64

(52) U.S. Cl. CPC G01R 31/52; H03M 1/645; H03F 3/45

(57) ABSTRACT

A resolver signal processing circuit for amplifying two phase signals output from a resolver includes first and second amplifier circuits configured to adjust an input in-phase voltage range to output an intended voltage even when a short-circuit arises in the resolver. The resolver signal processing circuit further includes first and second short-circuit detection circuits configured to detect the short-circuit arising in the resolver and short-circuits in first and second signal input paths from the resolver to the first and the second amplifier circuits, respectively, and first and second voltage adjusting units configured to adjust input in-phase voltage ranges of the first and second amplifier circuits when the first and second short-circuit detection circuits detect short-circuits, respectively. The first and second amplifier circuits are configured to adjust the input in-phase voltage ranges, respectively.

### CROSS REFERENCE TO RELATED APPLICATIONS

The present application is a continuation application of International Patent Application No. PCT/JP2019/015441 filed on Apr. 9, 2019, which designated the U.S. and claims the benefit of priority of Japanese Patent Application No. 2018-116196 filed on Jun. 19, 2018. The entire disclosures of both applications are incorporated herein by reference.

### FIELD

The present disclosure relates to a circuit that processes a signal output from a resolver.

### BACKGROUND

As one method of motor rotation angle detection, two-phase signals output from a resolver is used. According to this detection method, the two-phase signals are differentially input, amplified to differential type signals SINO and COSO respectively and input to a control circuit such as a microcomputer for signal processing to detect the motor rotation angle.

### SUMMARY

The present disclosure addresses the above problem and has an object to provide a resolver signal processing circuit that maintains a detection accuracy of a rotation angle even when a short-circuit arises in an input path of a signal output from a resolver.

According to the present disclosure, first and second amplifier circuits amplify two-phase signals output from a resolver, respectively, and output intended voltages by regulating an input in-phase voltage range when a short-circuit arises in the resolver. That is, the input in-phase voltage range is limited so that the output voltage is not affected. Thereby, even when a short-circuit arises in the resolver, the rotation angle can be detected based on the two-phase signals.

### BRIEF DESCRIPTION OF THE DRAWINGS

The above and other objects, features and advantages of the present disclosure will become more apparent from the following detailed description made with reference to the accompanying drawings. In the drawings:

FIG. 1 is a circuit diagram showing a configuration of a resolver signal processing circuit according to a first embodiment;

FIG. 2 is a flowchart showing processing contents of an MCU;

FIG. 3 is a circuit diagram showing a resistor connection state at the time of REF short-circuit;

FIG. 4 is a waveform diagram showing an output voltage waveform of a differential amplifier circuit corresponding to the state shown in FIG. 3;

FIG. 5 is a circuit diagram showing a resistor connection state at the time of a power short-circuit;

FIG. 6 is a waveform diagram showing an output voltage waveform of a differential amplifier circuit corresponding to the state shown in FIG. 5;

FIG. 7 is a circuit diagram showing a resistor connection state at the time of a ground short-circuit;

FIG. 8 is a waveform diagram showing an output voltage waveform of a differential amplifier circuit corresponding to the state shown in FIG. 7;

FIG. 9 is a circuit diagram showing a configuration of a resolver signal processing circuit according to a second embodiment;

FIG. 10 is a circuit diagram showing a voltage dividing state during a normal operation;

FIG. 11 is a waveform diagram showing an output voltage waveform of a digital signal processing unit corresponding to the state shown in FIG. 10;

FIG. 12 is a circuit diagram showing a voltage dividing state at the time of a REF short-circuit;

FIG. 13 is a waveform diagram showing an output voltage waveform of a digital signal processing unit corresponding to the state shown in FIG. 12;

FIG. 14 is a circuit diagram showing a resistor connection state at the time of a power short-circuit;

FIG. 15 is a waveform diagram showing an output voltage waveform of a differential amplifier circuit corresponding to the state shown in FIG. 14;

FIG. 16 is a circuit diagram showing a resistor connection state at the time of a ground short-circuit;

FIG. 17 is a waveform diagram showing an output voltage waveform of a differential amplifier circuit corresponding to the state shown in FIG. 16;

FIG. 18 is a circuit diagram showing a configuration of a resolver signal processing circuit according to a third embodiment;

FIG. 19 is a diagram showing output voltage waveforms of the differential amplifier circuit at the time of normal operation and a REF short-circuit, and

FIG. 20 is a waveform diagram showing an output voltage waveform of a differential amplifier circuit at the time of normal operation and REF short-circuit.

### DETAILED DESCRIPTION OF THE EMBODIMENT

### First Embodiment

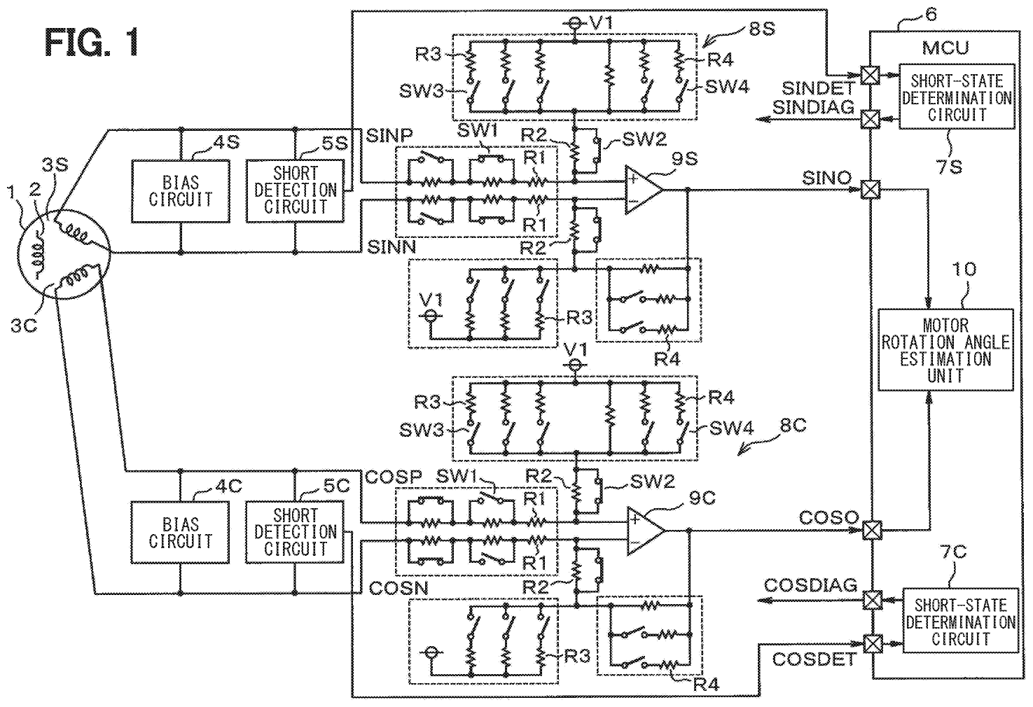

Referring first to FIG. 1, a resolver 1 includes a primary winding 2 and two secondary windings 3S, 3C. These windings 2 and 3 are insulated from each other. An excitation circuit (not shown) that supplies an excitation signal is connected to the primary winding 2. The secondary winding 3S outputs a SIN (sine) phase signal, and the secondary winding 3C outputs a COS (cosine) phase signal.

The primary winding 2 is connected to a rotor of a motor (not shown) whose rotation angle is to be detected. A mutual inductance between each of the secondary windings 3S, 3C and the primary winding 2 periodically changes according to a rotation angle θ of the rotor of the motor. As a result, output voltages of the secondary windings 3S and 3C become modulated waves produced by modulating the excitation signal with modulating waves SINO and COSO, respectively. The resolver 1 is mounted on a vehicle to detect the rotation angle of a drive motor for travel of an electric vehicle, for example.

One end and the other end of the secondary winding 3S are connected to signal lines SINP and SINN, respectively. A bias circuit 4S and a short-circuit detection circuit 5S are connected in parallel between the signal lines SINP and SINN. The bias circuit 4S applies a bias voltage that sets a center voltage of a resolver signal. The short-circuit detection circuit 5S is a resistor voltage dividing circuit for detecting a short-circuit on the SINO side, and a divided voltage output thereof is input to a short-circuit state determination circuit 7S inside an MCU 6 via an input terminal SINDET of the MCU 6.

The signal lines SINP and SINN are connected to respective input terminals of a differential amplifier circuit 8S. The differential amplifier circuit 8S is mainly composed of an operational amplifier 9S. Between the signal lines SINP, SINN and a non-inverting input terminal and an inverting input terminal of the operational amplifier 9S, a resistor R1 group including a plurality of series-connected resistors R1 is connected. A switch SW1 for short-circuiting is connected in parallel to a part of the resistors R1.

Between a power supply V1 and the non-inverting input terminal of the operational amplifier 9S, a resistor R2 is connected in series to a parallel circuit of a resistor R3 group and a resistor R4 group. The resistor R3 group has a configuration in which a plurality of series circuits of a resistor R3 and a switch SW3 are connected in parallel. The resistor R4 group also has a configuration in which a plurality of series circuits of a resistor R4 and a switch SW4 are connected in parallel. However, in the resistor R4 group, only one resistor R4 is connected in parallel to the series circuits. A switch SW2 for short-circuiting the resistor R2 is connected in parallel to the resistor R2.

Further, between the power supply V1 and the inverting input terminal of the operational amplifier 9S, the same series circuit of resistor R3 group and a resistor R2 as that on the non-inverting input terminal side is connected in series. The resistor R4 group is connected between an output terminal of the operational amplifier 9S and the resistor R2. It is noted that reference numerals and symbols are attached to only some of the circuit elements in order to avoid complication of the drawing. The output terminal of the operational amplifier 9S is connected to an input terminal of a motor rotation angle estimation unit 10 inside the MCU 6 via an input terminal SINO of the MCU 6. The configuration on the COS phase side is symmetrical to that on the SIN phase side. Hence, the corresponding configuration is indicated by “C” indicating a cosine signal path system instead of “S” indicating a sine signal path system in FIG. 1. The sine signal path system and the cosine signal path system form a first signal system and a second signal system, respectively. Structural components in the first signal system and the second signal system are identified with first and second, respectively, when necessary.

The motor rotation angle estimation unit 10 is configured to receive the output signals SINO and COSO of the differential amplifier circuits 8S and 8C and estimate the rotation angle of the motor. The short-circuit state determination circuits 7S and 7C are configured to determine whether a short-circuit state is present by receiving the input signals of the short-circuit detection circuits 5S and 5C and further determine a type of the short-circuit, that is, whether the short-circuit is a short-circuit to REF (referred to as a REF short-circuit or REF-short), a short-circuit to a power supply (referred to as a power short-circuit or power-short) or a short-circuit to a ground (referred to as a ground short-circuit or ground-short), when a short-circuit is arises. The REF short-circuit means a short-circuit among the primary and secondary windings 2, 3S and 3C in the resolver 1.

When a short-circuit arises, the short-circuit state determination circuits 7S and 7C respectively output diagnostic signals SINDIAG and COSDIAG according to the type of the short-circuit, and change on-off states of the switches SW1 to SW4 of the differential amplifier circuits 8S and 8C. That is, the diagnostic signals SINDIAG and COSDIAG indicate the type of short-circuit by 2-bit data. The short-circuit detection circuit 5 and the short-circuit state determination circuit 7 operate as a short-circuit detection circuit. Moreover, the short-circuit state determination circuit 7 operates as a voltage adjusting unit.

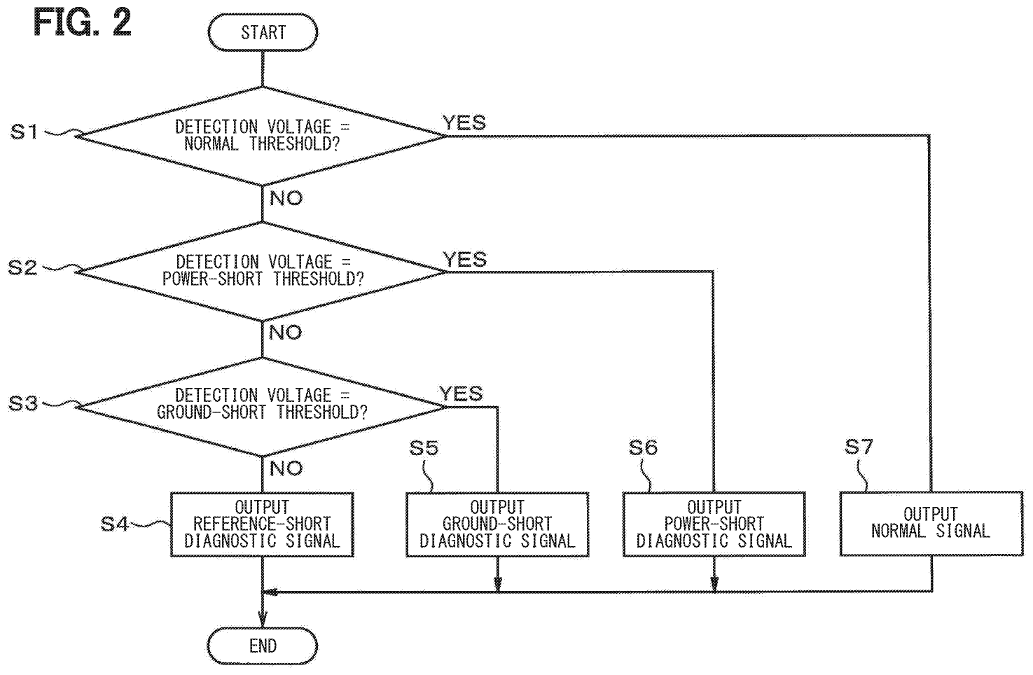

Next, operation of the present embodiment will be described. In the following description, “S” and “C” indicating the sine signal system and the cosine signal system are not used because both signal systems operate similarly. As shown in FIG. 2, the short-circuit state determination circuit 7 acquires a detection voltage (DET voltage) of the short-circuit detection circuit 4 and compares it with a normal threshold value (step S1), a power short-circuit threshold value (step S2), and a ground short-circuit threshold value (step S3), respectively. In case a circuit operating power supply voltage is 5V, for example, the normal threshold value is about 2.5V, the power short-circuit threshold value is 5V, and the ground short-circuit threshold value is 0V. If the DET voltage is equal to the normal threshold value, a normal signal is output (step S7). For example, the 2-bit data of the diagnostic signal is set to “00” indicating no short-circuit to make the diagnosis detection inactive.

If the DET voltage is different from the normal threshold value and equal to the power short-circuit threshold value, the 2-bit data of the diagnostic signal is set to “01,” for example, to output a diagnostic signal indicating the power short-circuit detection (step S6). If the DET voltage is different from the power short-circuit threshold value and equal to the ground short-circuit threshold value, the 2-bit data of the diagnostic signal to “10,” for example, to output a diagnostic signal indicating the ground short-circuit detection (step S5). Further, if the DET voltage is different from the power short-circuit threshold value, the 2-bit data of the diagnostic signal is set to “11,” for example, to output a diagnostic signal indicating the REF short-circuit detection (step S4).

In the present embodiment, each of the above three resistor groups R1, R3 and R4 each have a three-element configuration.

<Normal Operation Time>

At the time of normal operation (step S7) shown in FIG. 1, each switch SW is controlled as follows:

one switch SW1 in the resistor R1 group is turned on;

the switch SW2 of the resistor R2 is turned on;

all switches SW3 in the resistor R3 group are turned off; and

all switches SW4 in the resistor R4 group are turned off.

At this time, an input-output gain G0 of the operational amplifier 9 is given as follows.

G0=R4/(2×R1).

Therefore, an input voltage VINP0 of the operational amplifier 9S is given as follows.

VINP=V1−2×R1/(2×R1+R2+R4)×(V1−VSINP)

<REF Short-Circuit Time>

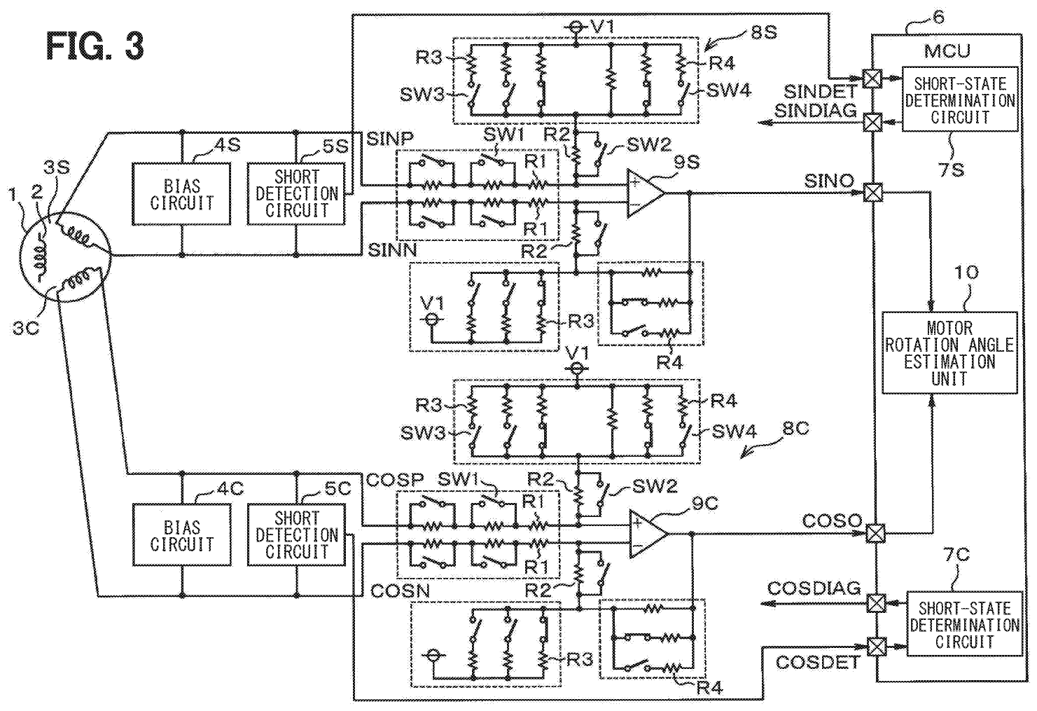

At the time of REF short-circuit (step S4) shown in FIG. 3, each switch SW is controlled as follows:

all switches SW1 in the resistor R1 group are turned off:

the switch SW2 of the resistor R2 is turned off;

one switch SW3 in the resistor R3 group is turned on; and

one switch SW4 in the resistor R4 group is turned on.

At this time, an input-output gain G1 of the operational amplifier 9 is given as follows.

G1={R2+R3//(R4/2)}/(3×R1)

An input voltage VINP1 of the operational amplifier 9S is given as follows.

VINP1=V1−3×R1/{3×R1+R2+R3//(R4/2)}×(V1−VSINP)

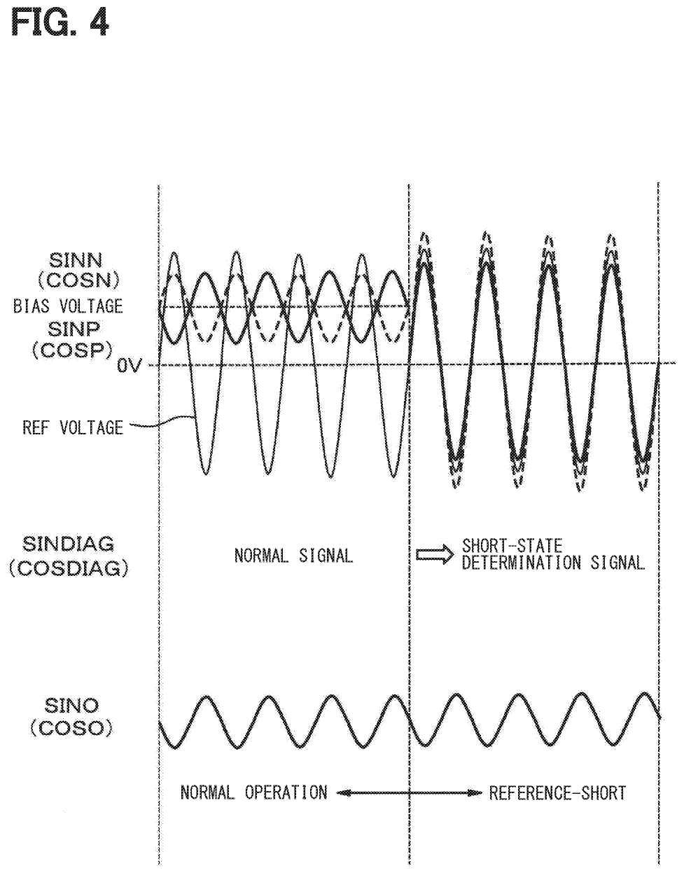

Here, it is assumed that, as shown in FIG. 4, the REF voltage is 2.5 V, and the SIN phase signal and the COS phase signal both have an amplitude of the REF voltage ±1.295 V at the normally operating time. When the REF short-circuit arises in this state, the amplitudes of the positive phase signal (normal phase signal) and the negative phase signal (reverse phase signal) of the SIN phase signal and the COS phase signal are as follows:

the positive phase signal is 0V±10.73V; and

the negative phase signal is 0V±13.32V.

Further, both signals are in-phase (common mode phase, that is, same phase).

On the other hand, by adjusting the input in-phase voltage range of the operational amplifier 9 in step S4, it is possible to prevent the output voltage waveform of the operational amplifier 9 from being distorted. Therefore, the MCU 6 can detect the rotation angle based on the two-phase signals as in the normal time.

<Power Short-Circuit Time>

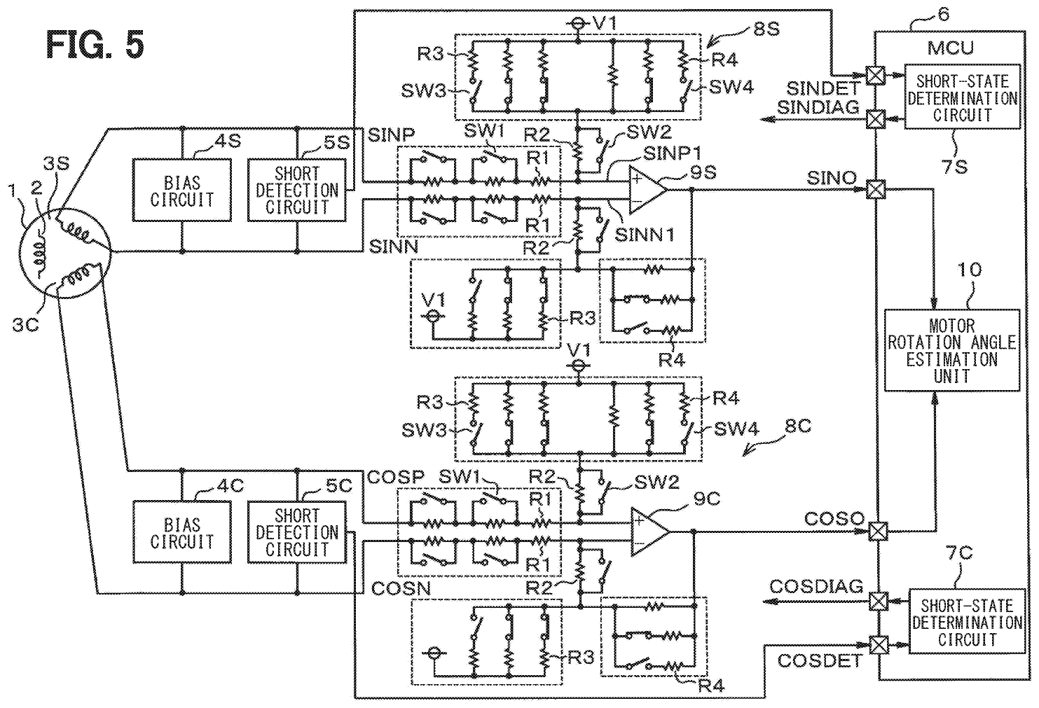

As shown in FIG. 5, each switch SW is controlled as follows at the time of the power short-circuit (step S6):

All switches SW1 in the resistor R1 group are turned off:

the switch SW2 of the resistor R2 is turned off;

two switches SW3 in the resistor R3 group are turned on; and

one switch SW4 in the resistor R4 group is turned on.

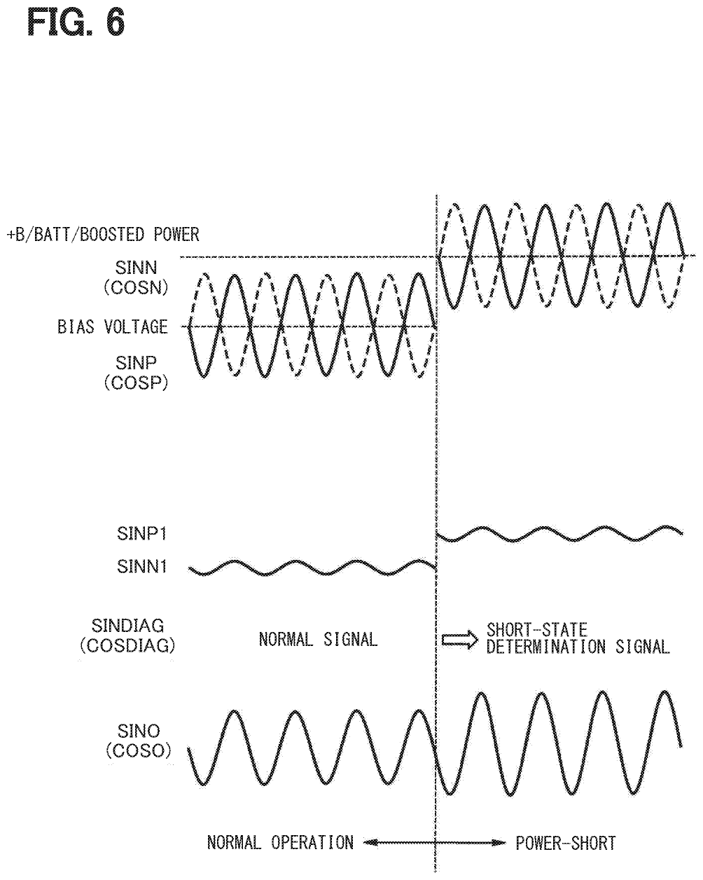

As shown in FIG. 6, at the time of the power short-circuit, the REF voltage rises to, for example, a battery voltage +B of a vehicle or to a boosted power supply voltage when a voltage boosting operation is performed. On the other hand, by adjusting the input in-phase voltage range as described above, the output voltage waveform of the operational amplifier 9 is prevented from being distorted.

<Ground Short-Circuit Time>

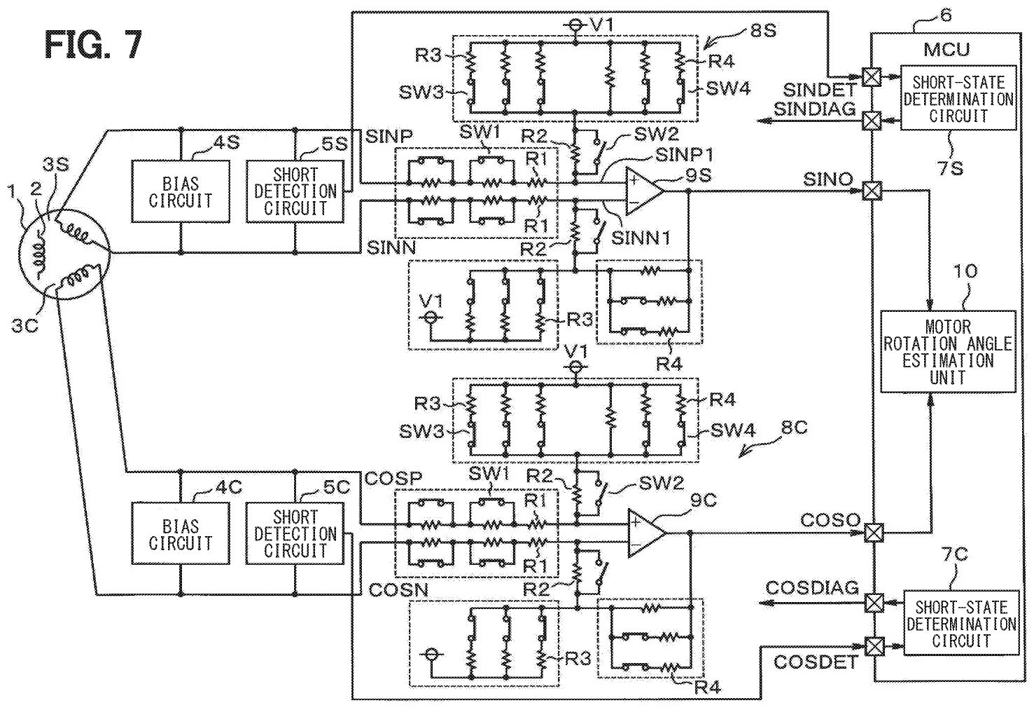

At the time of the ground short-circuit time (step S5) shown in FIG. 7, each switch SW is controlled as follows:

all switches SW1 in the first resistor R1 group are turned on;

the switch SW2 of the resistor R2 is turned off;

all switches SW3 in the resistor R3 group are turned on; and

all switches SW4 in the resistor R4 group are turned on.

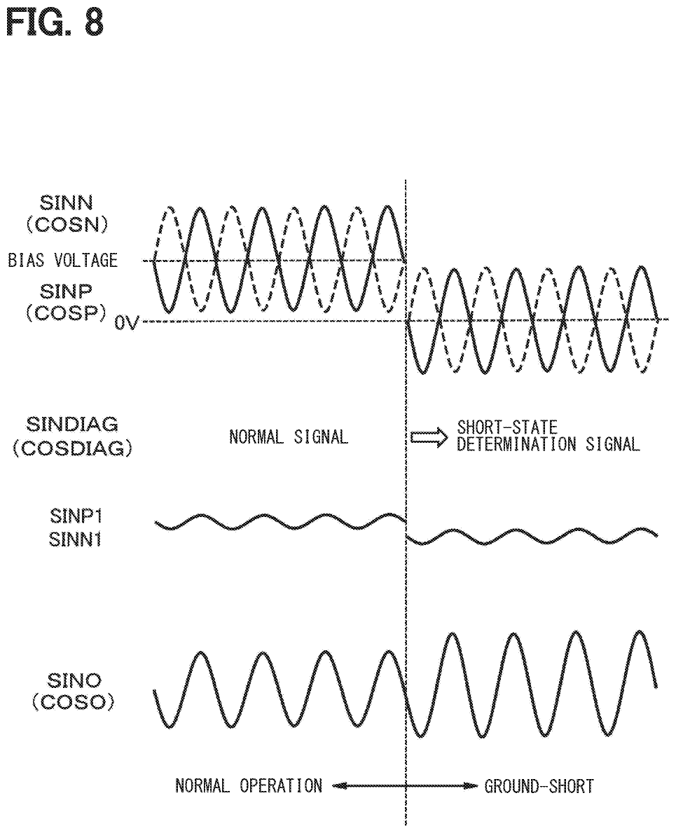

As shown in FIG. 8, at the ground short-circuit time, the REF voltage drops to 0V. However, by adjusting the input in-phase voltage range as described above, the MCU 6 can detect the rotation angle based on the two-phase signals as in the normal operation time.

As described above, according to the present embodiment, the short-circuit state determination circuits 7S and 7C respectively detect that a short-circuit has occurred in the resolver 1 or in the signal input path from the resolver 1 to the differential amplifier circuits 8S and 8C. When each short-circuit state determination circuit 7S, 7C detects the short-circuit, the input in-phase voltage range of the corresponding amplifier circuits 8S, 8C is changed. It is thus possible to dynamically limit the input in-phase voltage range so that the output voltage is not affected by the short-circuit. Since the MCU 6 can thus detect the rotation angle of the motor based on the two-phase signals as in the normal state, the electric vehicle can travel in the same manner as in the normal state and a limp-home traveling can be performed at high speed.

Further, the short-circuit state determination circuits 7S and 7C detect the winding short-circuit that occurs in the resolver 1 and the power short-circuit and the ground short-circuit that occur in the input path, and change the input in-phase voltage range of the differential amplifier circuits 8S and 8C. This input voltage range change can prevent the output voltage of the amplifier circuit 8 from being affected in each short-circuit case.

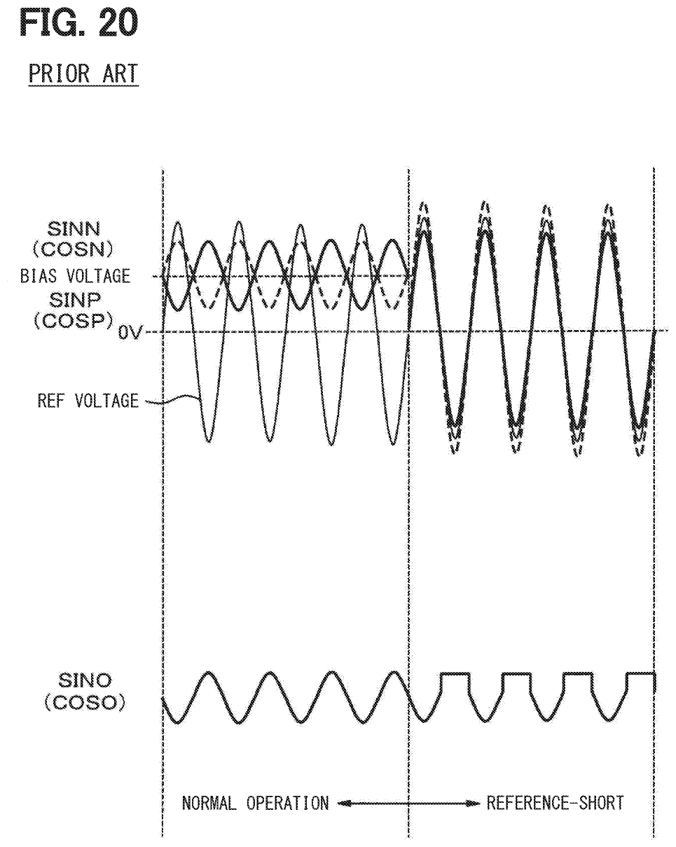

It is noted that, when a short-circuit of a winding arises in a resolver, the amplitude of the signal (SINO/COSO) used to detect the rotation angle increase. In this situation, as shown in FIG. 20, a signal waveform distorts. As a result, a sum of squares of a sine signal and a cosine signal does not become “1,” and the detection accuracy of the rotation angle is lowered. The first embodiment described above obviates this deficiency of the prior art.

### Second Embodiment

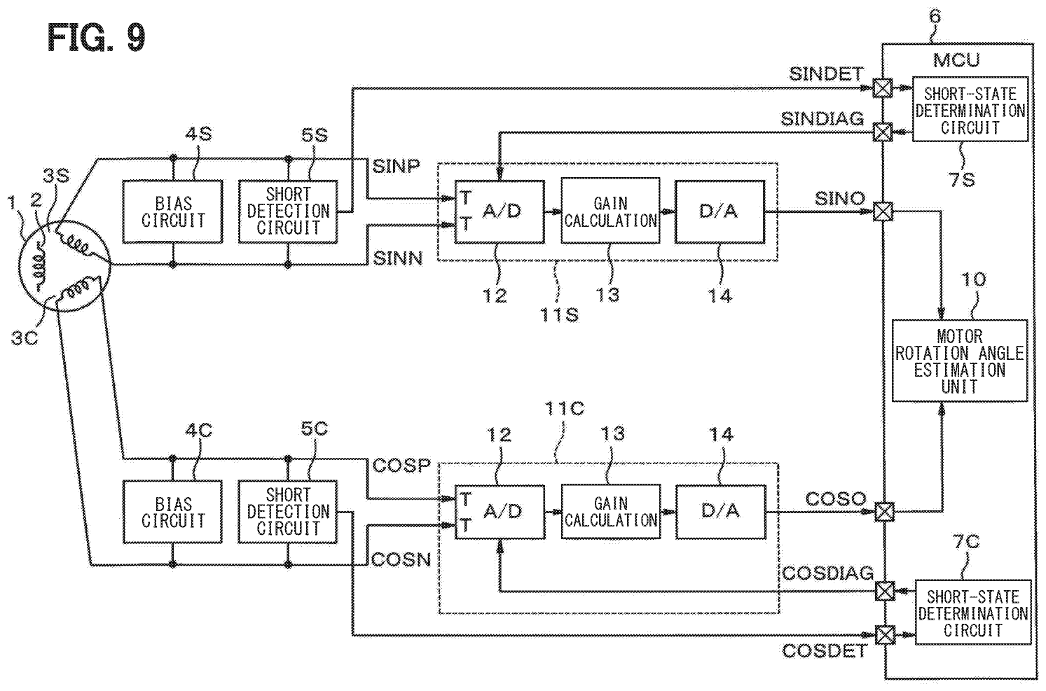

Hereinafter, the identical parts as those in the first embodiment will be designated by the same reference numerals for simplification of the description. Only differences from the first embodiment will be described below. As shown in FIG. 9, in a second embodiment, digital signal processing units 11S and 11C are arranged in place of the differential amplifier circuits 8S and 8C. The digital signal processing unit 11 (S, C) includes an A/D converter 12, a gain calculation unit 13 and a D/A converter 14. The digital signal processing units 11S and 11C correspond to first and second amplifier circuits, respectively. The gain calculation unit 13 corresponds to a gain setting unit.

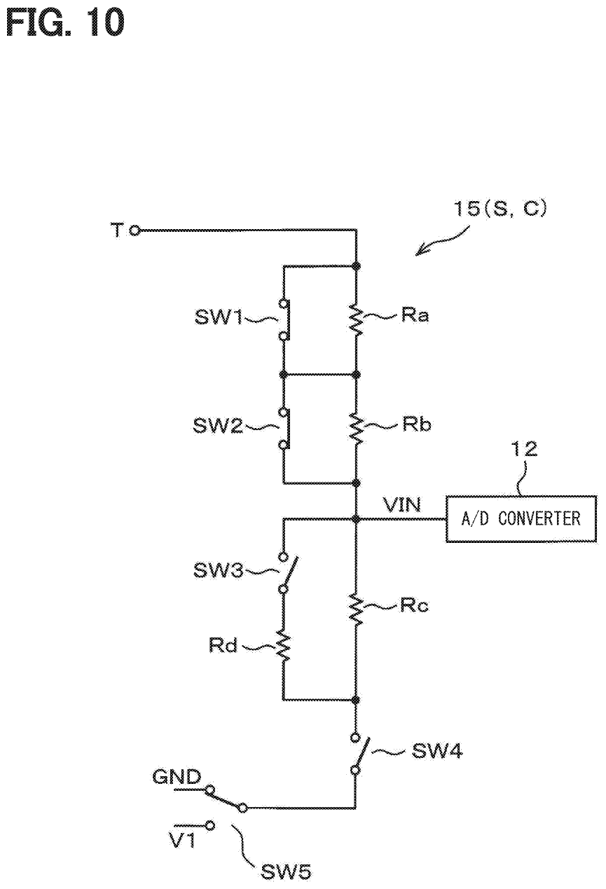

For example, as shown in FIG. 10, a voltage dividing circuit 15 (S, C) capable of changing a voltage dividing ratio of the input voltage is arranged on an input side of the A/D converter 12. A series circuit of resistors Ra and Rb is connected between a terminal T to which a voltage of each phase signal is applied and an input terminal VIN of the A/D converter 12. A series circuit of a resistor Rc and a switch SW40 is connected between the input terminal VIN and a changeover switch SW50.

Switches SW10 and SW20 are connected in parallel to the resistors Ra and Rb, respectively. A series circuit of a switch SW30 and a resistor Rd is connected in parallel to the resistor Rc. The changeover switch SW50 is provided to be connected to the power supply voltage V1 or the ground. The switches SW10 to SW50 are controlled by the signals SINDIAG and COSDIAG output from the short-circuit state determination circuits 7S and 7C to adjust the voltage division state in the voltage dividing circuit 15.

Operation of the second embodiment will be described next.

<Normal Operation Time>

As shown in FIG. 10, during a normal operation time, the switches SW10 to SW50 are controlled as follows:

the switch SW10 is turned on;

the switch SW20 is turned on;

the switch SW30 is turned on or off;

the switch SW40 is turned off; and

the switch SW50 is turned on or off.

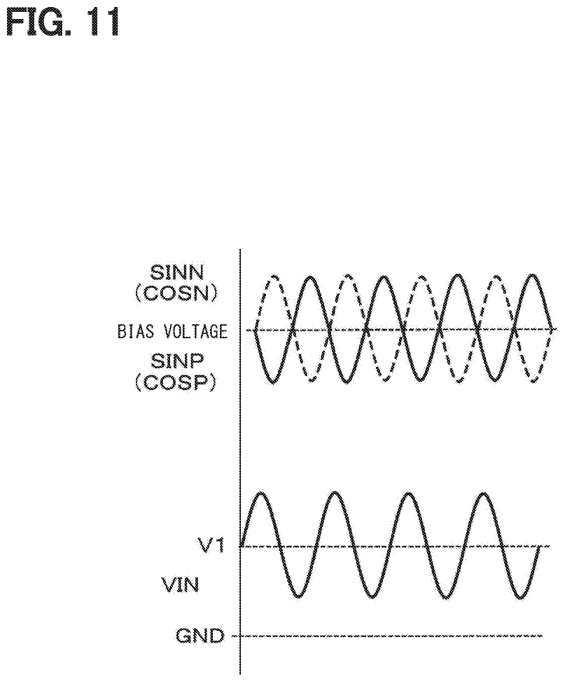

At this time, the voltage of the input terminal VIN is not divided and changes around the voltage V1 as shown in FIG. 11.

<REF Short-Circuit Time>

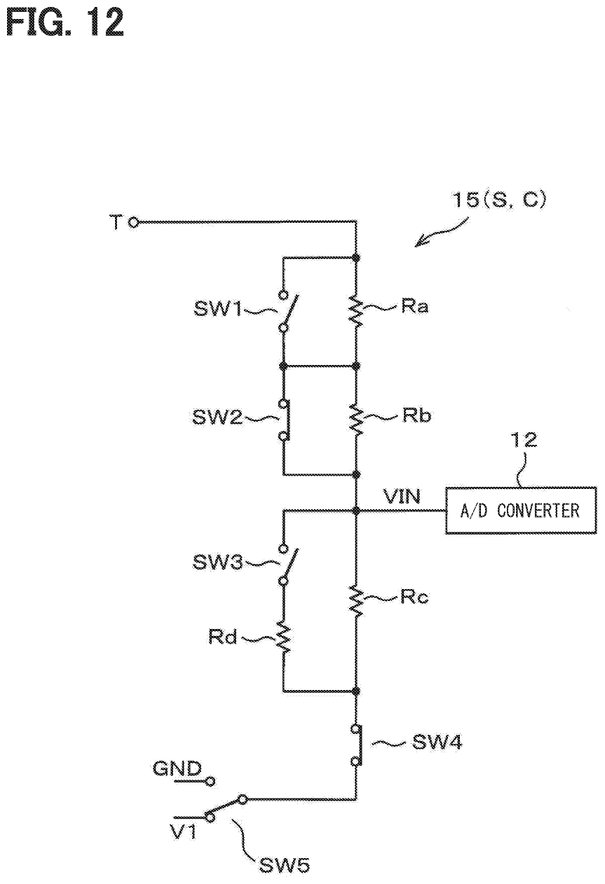

As shown in FIG. 12, each of the switches SW10 to SW50 is controlled as follows during the REF short-circuit time:

the switch SW10 is turned off;

the switch SW20 is turned on;

the switch SW30 is turned off;

the switch SW40 is turned on; and

the switch SW50 is turned to the voltage V1.

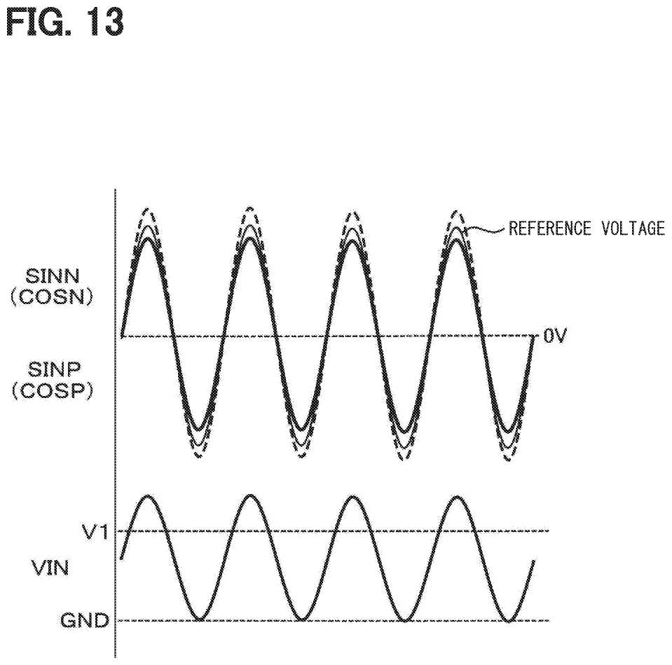

That is, as shown in FIG. 13, the voltage is divided by the ratio Rc/(Ra+Rc) with reference to the voltage V1 so that the voltage applied to the input terminal VIN does not become negative.

<Power Short-Circuit Time>

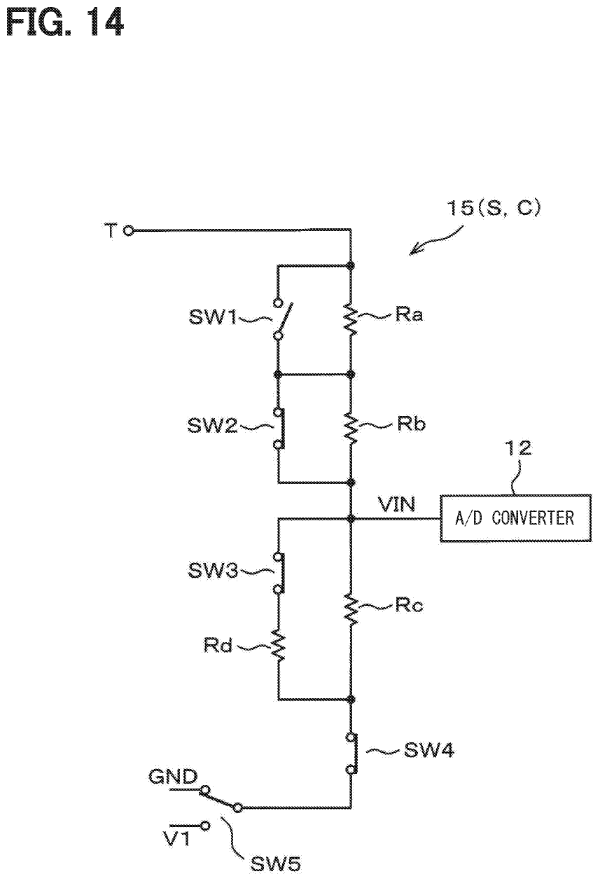

As shown in FIG. 14, each of the switches SW10 to SW50 is controlled as follows during the power short-circuit time:

the switch SW10 is turned off;

the switch SW20 is turned on;

the switch SW30 is turned on.

the switch SW40 is turned on; and

the switch SW50 is turned to the ground GND.

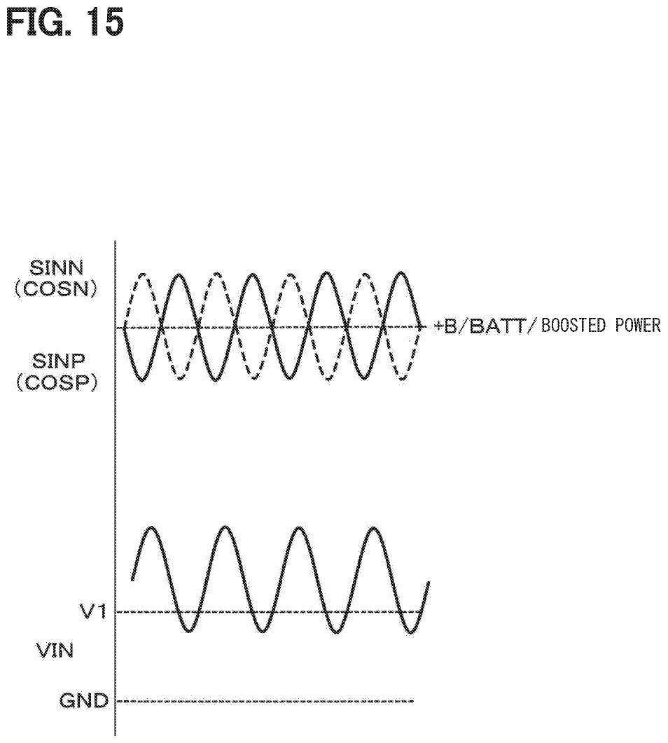

That is, as shown in FIG. 15, the voltage is divided by the ratio of Rc/(Ra+Rc//Rd) with reference to the ground so that the voltage applied to the input terminal VIN does not exceed the power supply voltage.

<Ground Short-Circuit Time>

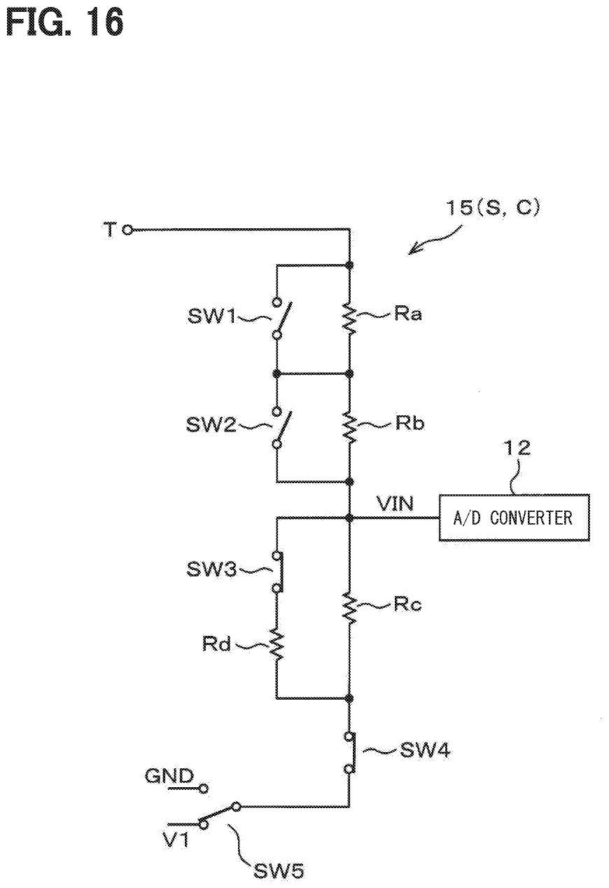

As shown in FIG. 16, each of the switches SW10 to SW50 is controlled as follows during the ground short-circuit time:

the switch SW10 is turned off;

the switch SW20 is turned off;

the switch SW30 is turned on.

the switch SW40 is turned on; and

the switch SW50 is turned to the voltage V1.

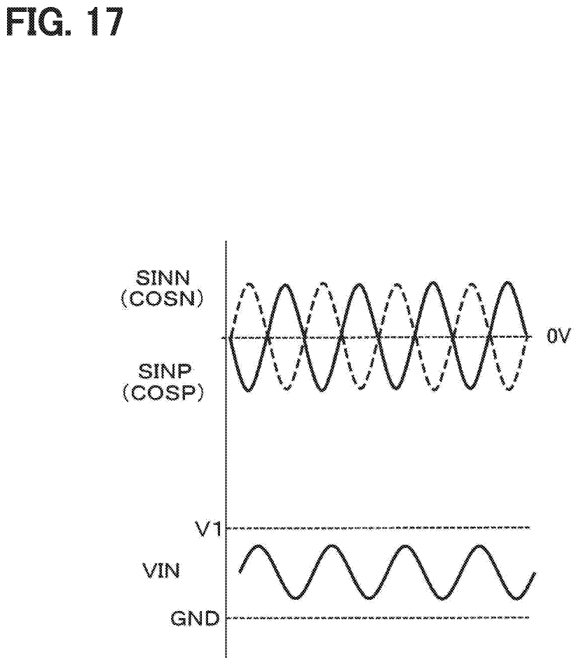

That is, as shown in FIG. 17, the voltage V1 is divided by the ratio Rc//Rd/(Ra+Rb+Rc//Rd) with reference to the voltage V1 so that the voltage applied to the input terminal VIN does not become negative.

As described above, according to the second embodiment, the digital signal processing units 11S and 11C include the voltage dividing circuits 15S and 15C that divide the two-phase signals, respectively, the A/D converters 12S and 12C that convert the divided voltages into the digital data, respectively, and the gain calculation units 13S and 13C that multiply the A/D converted data by a gain according to the amplification factor, respectively. The short-circuit state determination circuits 7S and 7C change the voltage division state in the voltage dividing circuits 15S and 15C, respectively. With this configuration, the same effect as that of the first embodiment can be provided even in case the two-phase signals are processed as digital data.

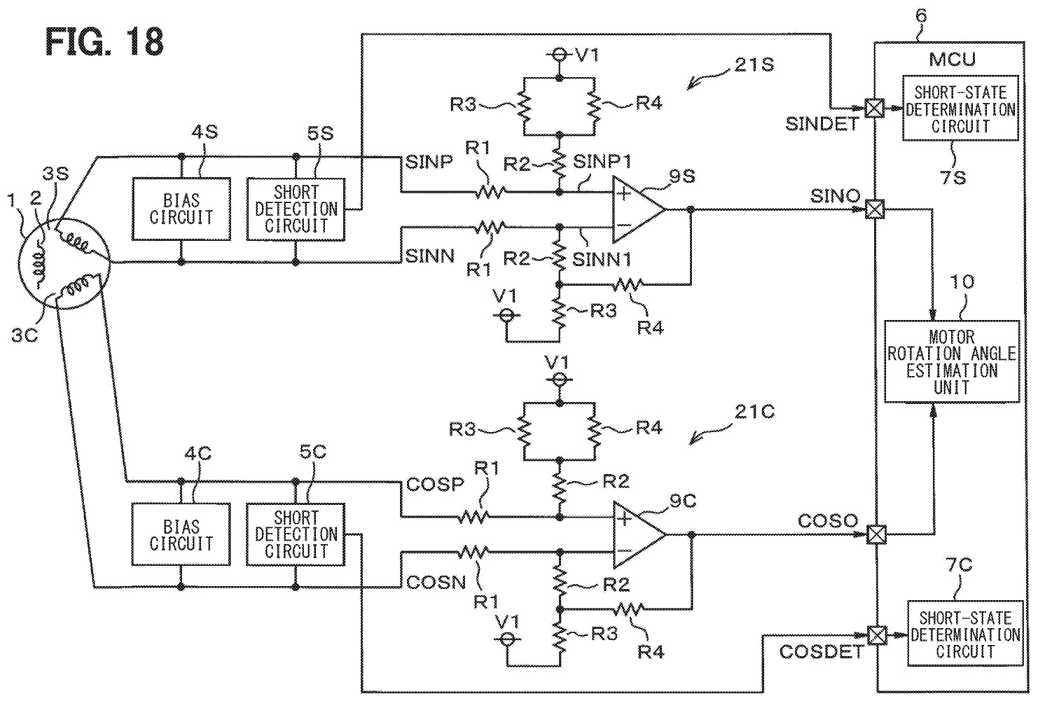

As shown in FIG. 18, according to a third embodiment, a differential amplifier circuits 21S and 21C are provided in place of the differential amplifier circuits 8S and 8C, respectively. In the present embodiment, the connection state of each resistor connected to the operational amplifier 9 is fixed. Each of the resistors R1 to R4 is formed of one resistance element. Except the resistor R4 whose one end is connected to the output terminal of the operational amplifier 9, the circuit configuration is in the same connection state as in the REF short-circuit case of the first embodiment. Therefore, the MCU 6 does not output the signals SINDIAG and COSDIAG.

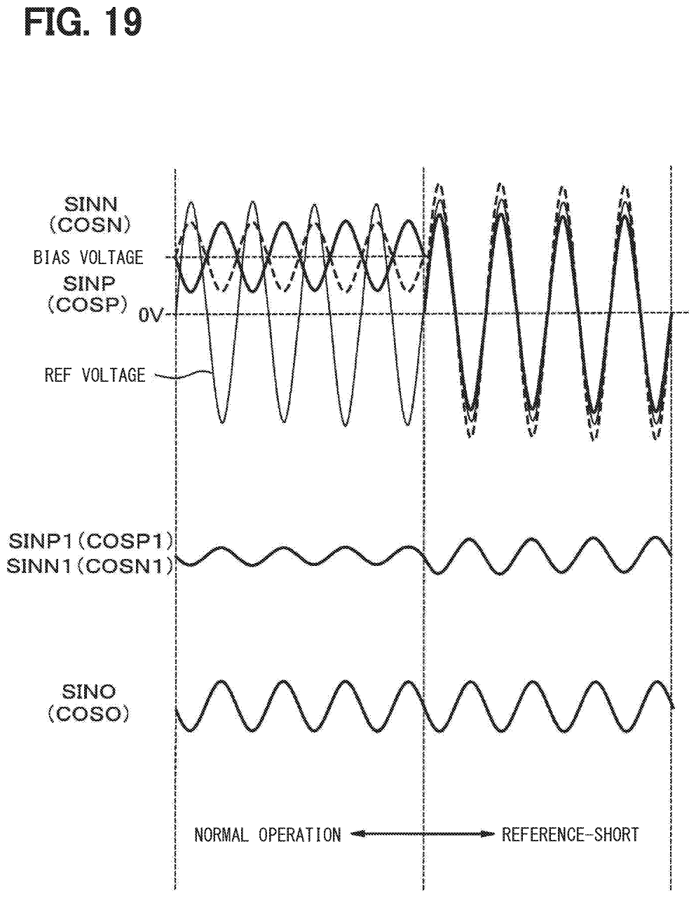

Next, operation of the third embodiment will be described. In the third embodiment, the circuit configuration is determined to meet only the REF-short circuit. Therefore, as shown in FIG. 19, even if the REF short-circuit arises in the normal operation state, the signal waveform of the output signal of the differential amplifier circuit 21 is not distorted as in the case shown in FIG. 4 of the first embodiment.

As described above, according to the third embodiment, the input in-phase voltage range in the differential amplifier circuits 21S and 21C is limited so that the output voltage is not affected when the REF short-circuit arises in the resolver 1. Therefore, when the MCU 6 detects the occurrence of the REF short-circuit, it is not necessary to switch the connection state of each resistor as opposed to the first embodiment.

### Other Embodiment

The number of resistors in each resistor group in the first embodiment, the number of the voltage dividing resistors in the second embodiment, and the like may be appropriately changed according to the individual design. The voltage values may also be appropriately changed according to the individual design. The target for detecting the rotation angle is not limited to the drive motor of the electric vehicle.

Although the present disclosure has been made in accordance with the embodiments, it is understood that the present disclosure is not limited to such embodiments and configurations. The present disclosure covers various modification examples and equivalent arrangements. In addition, various combinations and forms, and further, other combinations and forms including only one element, or more or less than these elements are also within the scope and the scope of the present disclosure.

1. A resolver signal processing circuit for amplifying two phase signals output from a resolver, the resolver signal processing circuit comprising:
first and second amplifier circuits configured to adjust an input in-phase voltage range to output an intended voltage even when a short-circuit arises in the resolver.

2. The resolver signal processing circuit according to claim 1, further comprising:
first and second short-circuit detection circuits configured to detect the short-circuit arising in the resolver and short-circuits in first and second signal input paths from the resolver to the first and the second amplifier circuits, respectively; and
first and second voltage adjusting units configured to adjust input in-phase voltage ranges of the first and second amplifier circuits when the first and second short-circuit detection circuits detect short-circuits, respectively,
wherein the first and second amplifier circuits are configured to adjust the input in-phase voltage ranges, respectively.

3. The resolver signal processing circuit according to claim 2, wherein:
each of the first and second amplifier circuits is configured by a differential amplifier circuit using an operational amplifier; and
each of the first and second voltage adjusting units is configured to change the input in-phase voltage range of the differential amplifier circuit.

4. The resolver signal processing circuit according to claim 2, wherein:
the first and second amplifier circuits include first and second voltage dividing circuits configured to divide the two-phase signals respectively, first and second A/D converters configured to convert voltages divided by the first and second voltage dividing circuits into digital data respectively, and first and second gain setting units configured to multiply the digital data of the first and second A/D converters by gains set in accordance with amplification ratios respectively; and
the first and second voltage adjusting units change voltage dividing states of the first and second voltage dividing circuits, respectively.

5. The resolver signal processing circuit according to claim 2, wherein:
the first and second short-circuit detection circuits are configured to detect the short-circuit in windings of the resolver, the short-circuit of the first and second input paths to a power supply and to a ground, respectively; and
the first and second voltage adjusting units are configured to change the input in-phase voltage ranges of the first and second amplifier circuits in correspondence to a type of the short-circuit detected by the first and second short-circuit detection circuits, respectively.

6. The resolver signal processing circuit according to claim 3, wherein:
the first and second short-circuit detection circuits are configured to detect the short circuit in windings of the resolver, the short-circuit of the first and second input paths to a power supply and to a ground, respectively; and
the first and second voltage adjusting units are configured to change the input in-phase voltage ranges of the first and second amplifier circuits in correspondence to a type of the short-circuit detected by the first and second short-circuit detection circuits, respectively.

7. The resolver signal processing circuit according to claim 4, wherein:
the first and second short-circuit detection circuits are configured to detect the short circuit in windings of the resolver, the short-circuit of the first and second input paths to a power supply and to a ground, respectively; and
the first and second voltage adjusting units are configured to change the input in-phase voltage ranges of the first and second amplifier circuits in correspondence to a type of the short-circuit detected by the first and second short-circuit detection circuits, respectively.

8. A resolver signal processing circuit for amplifying two phase signals output from a resolver attached to a motor, the resolver signal processing circuit comprising:
a differential amplifier;
a plurality of resistor groups connected between the resolver and the differential amplifier and configured to vary a voltage input from the resolver to the differential amplifier in response to a diagnostic signal applied thereto, each of the resistor groups including resistors and switches; and
a control unit configured to determine a rotation angle of the motor based on an output signal of the differential amplifier, determine a short-circuit state including a short-circuit in the resolver, a short-circuit of the signal input path to a power supply and a short-circuit of the signal input path to a ground, and control on-off states of the switches in the plurality of resistor groups to vary resistances of the plurality of resistor groups and thereby vary an input voltage range of the differential amplifier in correspondence to a determined short-circuit state.
